(19) United States
(12) Patent Application Publication
(10) Pub. No.: US 2014/0024184 A1
(43) Pub. Date: Jan. 23, 2014

(54) Semiconductor device and method for making semiconductor device

(71) Applicant: Infineon Technologies AG, Neubiberg (DE)

(72) Inventors: John POWER, Tainan City (TW); Danny Pak-Chum SHUM, Poughkeepsie (TW)

(21) Appl. No.: 13/972,958

(22) Filed: Aug. 22, 2013

Related U.S. Application Data
(62) Division of application No. 12/138,457, filed on Jun. 13, 2008.

(51) Int. Cl. H01L 29/66

(52) U.S. Cl. CPC H01L 29/66825
USPC 438/257

(57) ABSTRACT

One or more embodiments relate to a memory device, comprising: a substrate; a gate stack disposed over the substrate, the gate stack comprising a charge storage layer and a high-k dielectric layer; and a cover layer disposed over at least the sidewall surfaces of the high-k dielectric layer.

### RELATED APPLICATION INFORMATION

The present application is a divisional application of U.S. patent application Ser. No. 12/138,457, filed on Jun. 13, 2008. U.S. patent application Ser. No. 12/138,457 is hereby incorporated by reference herein.

### FIELD OF THE INVENTION

The present invention relates to semiconductor devices and methods for making semiconductor devices.

### BACKGROUND OF THE INVENTION

Semiconductor devices are used in many electronic and other applications. Semiconductor devices comprise integrated circuits that are formed on semiconductor wafers by depositing many types of thin films of material over the semiconductor wafers, and patterning the thin films of material to form the integrated circuits.

One type of semiconductor device is a memory device, in which data is typically stored as a logical “1” or “0”. One type of memory device is a charge storage memory device. The charge storage memory device may, for example, be a floating gate memory device or a charge trapping memory device.

### SUMMARY OF THE INVENTION

An embodiment is a memory device, comprising: a substrate; a gate stack disposed over said substrate, said gate stack comprising a charge storage layer and a high-k dielectric layer; and a cover layer disposed over at least the sidewall surfaces of the high-k dielectric layer.

An embodiment is a method of making a memory device, the memory device including a charge storage layer, the method comprising: providing a substrate; forming a gate stack over the substrate, the gate stack comprising the charge storage layer and a high-k dielectric layer; and forming a cover layer over at least the exposed surfaces of the high-k dielectric layer.

An embodiment is a method of making a memory device, comprising: providing a substrate; forming a gate stack over the substrate, the gate stack including: a first dielectric layer, a charge storage layer formed over the first dielectric layer, a second dielectric layer formed over the charge storage layer, and a control gate layer formed over the second dielectric layer, at least one of the first dielectric layer or the second dielectric layer comprising a high-k dielectric material; and forming a cover layer over the sidewall surfaces of the gate stack so an to cover at least the high-k dielectric material.

### BRIEF DESCRIPTION OF THE DRAWINGS

FIG. 1 shows a stack of layers over a substrate in accordance with an embodiment;

FIG. 2 shows a gate stack in accordance with an embodiment;

FIG. 3A shows a gate stack in accordance with an embodiment;

FIG. 3B shows a gate stack in accordance with an embodiment;

FIG. 3C shows a gate stack in accordance with an embodiment;

FIG. 4 shows the formation of a cover layer in accordance with an embodiment;

FIG. 5 shows the formation of source/drain extension regions in accordance with an embodiment;

FIG. 6 shows the formation of sidewall spacers in accordance with an embodiment;

FIG. 7 shows the formation of source/drain regions in accordance with an embodiment;

FIG. 8 shows an embodiment of a gate stack in accordance with an embodiment;

FIG. 9 shows the formation of a pre-cover layer in accordance with an embodiment;

FIG. 10 shows the formation of a cover layer in accordance with an embodiment;

FIG. 11 shows the formation of source/drain extension regions in accordance with an embodiment;

FIG. 12 shows the formation of sidewall spacers in accordance with an embodiment; and

FIG. 13 shows the formation of source/drain regions in accordance with an embodiment.

### DETAILED DESCRIPTION OF THE INVENTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

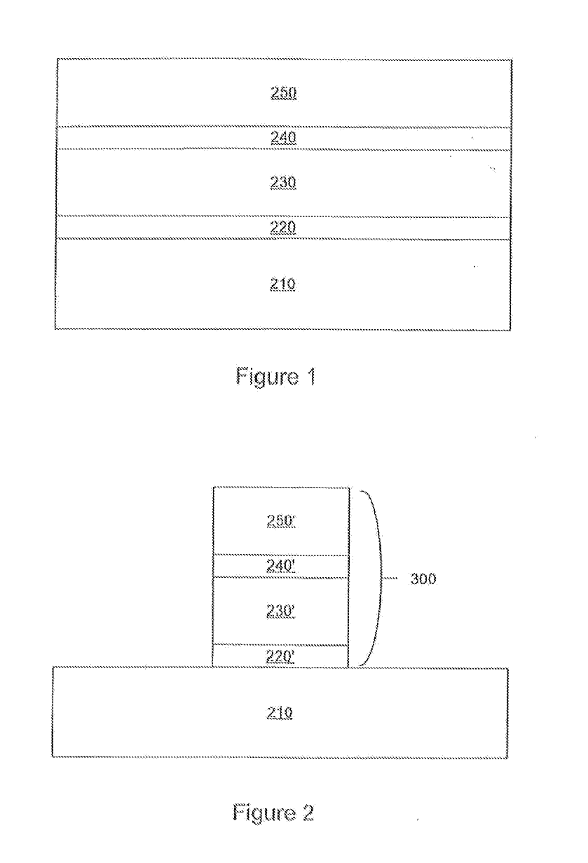

FIGS. 1 through 6 show an embodiment for making a semiconductor device. Referring to FIG. 1, a semiconductor substrate 210 is provided. The substrate 210 may be any type of substrate. In an embodiment, the substrate 210 may be a p-type substrate. However, more generally, in one or more embodiments of the invention, the substrate may be a silicon substrate or other suitable substrate. The substrate may, for example, be a bulk mono-crystalline silicon substrate (or a layer grown thereon or otherwise formed therein), a layer of (110) silicon on a (100) silicon wafer, or a silicon-on-insulator (SOI) substrate. The SOI substrate may, for example, be formed by a SIMOX process. The SOI substrate, may, for example, be formed by wafer bonding. The substrate may be a silicon-on-sapphire (SOS) substrate. The substrate may be a germanium-on-insulator (GeOI) substrate. The substrate may include one or more materials such as semiconductor materials. The substrate may include one or more material such as silicon germanium, germanium, germanium arsenide, indium arsenide, indium arsenide, indium gallium arsenide, or indium antimonide.

Next, a first dielectric layer 220 is formed over the substrate 210. In one or more embodiments, the first dielectric layer 220 may comprise an oxide (such as silicon dioxide SiO₂), a nitride (such as Si₃N₄ or SiₓN_{y}), an oxynitride (such as, for example, silicon oxynitride, S—O—N or SiOₓN_{y}), an oxide/nitride stack (such as a SiOₓ/SiₓN_{y} stack), a nitride/oxide stack, an oxide/nitride/oxide stack (for example, an ONO stack) or combinations thereof.

In one or more embodiments, the first dielectric layer may comprise a high-k dielectric material. A high-k dielectric material may also referred to as a high-k material. In one or more embodiments, the high-k dielectric material may have a dielectric constant greater than 3.9. In one or more embodiments, the high-k dielectric material may have a dielectric constant greater than that of silicon dioxide. In one or more embodiments, the high-k material may comprise a hafnium-based material. In one or more embodiments, the high-k material may comprise one or more of the elements Hf, Al, Si, Zr, O, N, Ta, La, Ti, Y, Pr, Gd and combinations thereof. The high-k material may, for example, comprise HfSiON, HfSiO, HfO₂, HfSiOₓ, HfAlOₓ, HfAlOₓN_{y}, HfSiAlOₓ, HfSiAl0ₓN_{y}, Al₂O₃, ZrO₂, ZrSiOₓ, Ta₂O₅, SrTiO₃, La₂O₃, Y₂O₃, Gd₂O₃, Pr₂O₃, TiO₂, ZrAlOₓ, ZrAlOₓN_{y}, SiAlOₓ, SiAlOₓN_{y}, ZrSiAlOₓ, ZrSiAlOₓN_{y}, or combinations thereof. In one or more embodiments, the high-k material may comprise Al₂O₃.

In one or more embodiments, the first dielectric layer 220 may comprise any other dielectric material or high-k dielectric material. In one or more embodiments, the first dielectric layer 220 may comprise an oxide/high-k stack such as a SiO₂/Al₂O₃ stack. In one or more embodiments, the first dielectric layer 220 may comprise a high-k/oxide stack such as an Al₂O₃/SiO₂.

In one or more embodiments, the first dielectric layer may have a thickness of at least 4 nm (nanometers). In one or more embodiments, the first dielectric layer may have a thickness greater than about 6 nm. In one or more embodiments, the first dielectric layer may have a thickness greater than about 8 nm. In one or more embodiments, the first dielectric layer may have a thickness of less than about 15 nm. In one or more embodiments, the first dielectric layer may have a thickness of less than about 12 nm. In one or more embodiments, the first dielectric layer may comprise a single layer of material or it may comprise two or more layers of material.

The first dielectric layer 210 may be formed in many different ways. For example, the first dielectric layer may be grown by a thermal oxidation, deposited by a chemical vapor deposition (CVD), atomic layer deposition (ALD), physical vapor deposition (PVD), or a jet vapor deposition. Hence, the first dielectric layer may be formed by a growth process or by a deposition process. In one or more embodiments, the first dielectric layer 220 may be an oxide form by a thermal oxidation process. In one or more embodiments, the oxide may be silicon dioxide.

A high-k dielectric material may be formed, for example, by a deposition process. Examples of deposition process which may be used include chemical vapor deposition (CVD), physical vapor deposition (PVD), atomic layer deposition (ALD), molecular beam epitaxy (MBE), or other deposition processes.

In one or more embodiments, the first dielectric layer may serve as a tunneling dielectric layer for a charge storage memory device such as a floating gate memory device or for a charge trapping memory device.

Next, a charge storage layer 230 may be formed over the first dielectric layer 220. In one or more embodiments, the charge storage layer 230 may comprise any conductive material. In one or more embodiments, the charge storage layer 230 may comprise, for example, a polysilicon material. The polysilicon may be doped with an n-type dopant (such as phosphorus) or a p-type dopant (such as boron). The doping may be accomplished using an ion implantation process. The doping may be done in-situ. In one or more embodiments, the charge storage layer 230 may comprise a metallic material such as a pure metal or a metal alloy. In one or more embodiments, the charge storage layer 230 may comprise a conductive material. In one or more embodiments, the charge storage layer 230 may comprise a semiconductor material. In one or more embodiments, the charge storage layer 230 may comprise a dielectric material. The dielectric material, may, for example, be a nitride material such as a silicon nitride material. In one or more embodiments, the charge storage layer 230 may comprise a metal silicide or a metal nitride.

In one or more embodiments, the charge storage layer 230 may comprise TiN, TiC, HfN, TaN, TaC, TaN, W, Al, Ru, RuTa, TaSiN, NiSix, CoSix, TiSiₓ, Ir, Y, Pt, I, Pt, Ti, Pd, Re, Rh, borides of Ti, borides of Hf, borides of Zr, phosphides of Ti, phosphide of Hf, phoshides of Zr, antimonides of Ti, antimonides of Hf, antimonides of Zr, TiAlN, Mo, MoN, ZrSiN, ZrN, HfN, HfSiN, WN, Ni, Pr, VN, TiW, and/or combinations thereof.

In one or more embodiments, the charge storage layer 230 may comprise a nitride material such as a silicon nitride material. In one or more embodiments, the charge storage material 230 may include an oxynitride material. In one or more embodiments, the charge storage material 230 may include a nanocrystalline material. In one or more embodiments, the charge storage material may include a high-k dielectric material.

In one or more embodiments, the charge storage layer 230 may serve as a floating gate layer for a floating gate of a floating gate memory device. Hence, in one or more embodiments, the charge storage layer 230 may be formed of any material which can serve as a floating gate of a floating gate memory device.

In one or more embodiments, the floating gate material may comprise any conductive material. In one or more embodiments, the floating gate material may comprise, for example, a polysilicon material. The polysilicon may be doped with an n-type dopant (such as phosphorus) or a p-type dopant (such as boron). The doping may be accomplished using an ion implantation process. The doping may be done in-situ.

In one or more embodiments, the floating gate material may comprise a metallic material such as a pure metal or a metal alloy. In one or more embodiments, the floating gate material may comprise a conductive material. In one or more embodiments, the charge storage layer 230 may comprise a semiconductor material. In one or more embodiments, the floating gate material may comprise a dielectric material. The dielectric material, may, for example, be a nitride material such as a silicon nitride material. In one or more embodiments, the floating gate material may comprise a metal silicide or a metal nitride.

In one or more embodiments, the floating gate material may comprise TiN, TiC, HfN, TaN, TaC, TaN, W, Al, Ru, RuTa, TaSiN, NiSix, CoSix, TiSiₓ, Ir, Y, Pt, I, Pt, Ti, Pd, Re, Rh, borides of Ti, borides of Hf, borides of Zr, phosphides of Ti, phosphide of Hf, phoshides of Zr, antimonides of Ti, antimonides of Hf, antimonides of Zr, TiAlN, Mo, MoN, ZrSiN, ZrN, HfN, HfSiN, WN, Ni, Pr, VN, TiW, and/or combinations thereof.

Examples, of floating gate materials include, but not limited to, conductive materials such as, for example, polysilicon materials. Examples of polysilicon materials include n-doped and p-doped polysilicon materials.

In one or more embodiments, the charge storage layer 230 may be a charge trapping layer. In this case, the charge storage memory device may be a charge trapping memory device. Charges may be stored within traps of the charge trapping material. In one or more embodiments, the charge trapping layer may comprise a nitride material such as a silicon nitride material. In one or more embodiments, the charge trapping layer may comprise a nanocrystalline layer. In one or more embodiments, the charge trapping layer may comprise a high-k dielectric material.

The charge storage layer 230 may comprise a single layer or a plurality of stacked layers (such as a polysilicon layer disposed over a metal layer). In one or more embodiments, the thickness of the charge storage layer 230 may be about 300 Angstroms to about 3000 Angstroms, however, other thicknesses are also possible. The charge storage layer 230 may be deposited in many different ways. Examples include chemical vapor deposition, physical vapor deposition and atomic layer deposition.

Next, a second dielectric layer 240 is disposed over the charge storage layer. In one or more embodiments, the second dielectric layer 240 may comprise an oxide (such as silicon dioxide SiO₂), a nitride (such as Si₃N₄ or SiₓN_{y}) an oxynitride, such as silicon oxynitride (S—O—N or SiOₓN_{y}), an oxide/nitride stack such as a SiO₂/Si₃N₄ or an Si02/SiₓN_{y} stack (where the layers may be in any order), an oxide/nitride/oxide stack (for example, an ONO stack) or combinations thereof. The second dielectric layer 240 may, for example, be formed from a growth process or a deposition process.

In one or more embodiments, the second dielectric layer 240 may comprise a high-k dielectric material. In one or more embodiments, the high-k dielectric material may have a dielectric constant greater than 3.9. In one or more embodiments, the high-k dielectric material may have a dielectric constant greater than silicon dioxide. In one or more embodiments, the high-k material may comprise a hafnium-based material. In one or more embodiments, the high-k material may comprise one or more of the elements Hf, Al, Si, Zr, O, N, Ta, La, Ti, Y, Pr, Gd and combinations thereof. In one or more embodiments, the high-k material may comprise HfSiON, HfSiO, HfO₂, HfSiOₓ, HfAlOₓ, HfAlOₓN_{y}, HfSiAlOₓ, HfSiAlOₓN_{y}, Al₂O₃, ZrO₂, ZrSiOₓ, Ta₂O₅, SrTiO₃, La₂O₃, Y₂O₃, Gd₂O₃, Pr₂O₃, TiO₂, ZrAlOₓ, ZrAlOₓN_{y}, SiAlOₓ, SiAlOₓN_{y}, ZrSiAlOₓ, ZrSiAlOₓN_{y}, or combinations thereof. In one or more embodiments, the high-k dielectric material may comprise Al₂O₃. In one or more embodiments, the second dielectric layer 240 may comprise any other dielectric material or any other high-k dielectric material.

In one or more embodiment, the first dielectric layer 220 may comprise a high-k dielectric material. In one or more embodiments, the second dielectric layer 240 may comprise a high-k dielectric material. In one or more embodiments, the first dielectric layer 220 may comprise a first high-k dielectric material and the second dielectric layer 240 may comprise a second high-k dielectric material. In an embodiment, the first high-k dielectric material may be the same as the second high-k dielectric material. In an embodiment, the first high-k dielectric material may be different from the second high-k dielectric material.

In one or more embodiments, the second dielectric layer 240 may have a thickness of at least 4 nm (nanometers). In one or more embodiments, the second dielectric layer may have a thickness greater than about 6 nm. In one or more embodiments, the second dielectric layer may have a thickness greater than about 8 nm. In one or more embodiment, the second dielectric layer may have a thickness of less than about 20 nm. In one or more embodiments, the second dielectric layer may have a thickness of less than about 12 nm. In one or more embodiments, the second dielectric layer may comprise a single layer of material or it may comprise two or more layers of material.

The second dielectric layer 240 may be formed in many different ways. For example, the second dielectric layer may be grown by a thermal growth process (such as thermal oxidation), deposited by a chemical vapor deposition (CVD), atomic layer deposition (ALD), physical vapor deposition (PVD), or a jet vapor deposition. Hence, the second dielectric layer may be formed by a growth process or by a deposition process.

A high-k material may be formed, for example, by a deposition process. Examples of deposition process which may be used include chemical vapor deposition (CVD), physical vapor deposition (PVD), atomic layer deposition (ALD), molecular beam epitaxy (MBE), Metal-Organic Chemical Vapor Deposition (MOCVD), or other deposition processes.

In one or more embodiments, the second dielectric layer 240 may serve as an inter-gate dielectric layer between a floating gate and a control gate of a floating gate memory device. In one or more embodiments, the floating gate and the control gate may both be formed of a polysilicon material. The polysilicon material may be n-doped or p-doped. In this case, the second dielectric layer may be referred to as an interpoly dielectric material.

It is noted that the use of a high-k material as an inter-gate dielectric layer (or as an interpoly dielectric layer) in a floating gate memory device may be beneficial since the larger dielectric constant may lead to larger capacitive coupling between the control gate and the floating gate. This may lead to a reduction in the power needed to operate the device.

The second dielectic material 240 may also be used between the charge trapping layer and the control gate layer of a charge trapping device. The second dielectric material 240 may serve as a blocking dielectric to block the transfer of charges to and from the charge storage layer. Likewise, the use of a high-k material in a charge trapping device between a control gate and a charge trapping layer may also be beneficial.

Next, a control gate layer 250 is formed over the second dielectric layer. In one or more embodiments, the control gate layer 250 may comprise any conductive material. In one or more embodiments, the control gate layer 250 may comprise, for example, a polysilicon material. In one or more embodiments, the polysilicon may be doped with an n-type dopant (such as phosphorus). In one or more embodiments, the polysilicon may be p-type dopant (such as boron). The doping may, for example, be accomplished using an ion implantation process. At least a portion of the doping may be accomplished during source/drain formation. At least a portion of the doping may be accomplished during source/drain extension formation. In one or more embodiments, it is also possible that doping may be in situ.

In one or more embodiments, the control gate layer 250 may comprise a metallic material such as a pure metal or a metal alloy. In one or more embodiments, the control gate layer may be any material suitable as a control gate for a floating gate device. In one or more embodiments, the control gate layer 250 may comprise a metal silicide or a metal nitride. In one or more embodiments, the second gate layer 270 may comprise TiN, TiC, HfN, TaN, TaC, TaN, W, Al, Ru, RuTa, TaSiN, NiSix, CoSix, TiSiₓ, Ir, Y, Pt, I, PtTi, Pd, Re, Rh, borides, phosphides, or antimonides of Ti, Hf, Zr, TiAlN, Mo, MoN, ZrSiN, ZrN, HfN, HfSiN, WN, Ni, Pr, VN, TiW, other metals, and/or combinations thereof.

The control gate layer 250 may comprise a single layer or a plurality of stacked layers (such as a polysilicon layer disposed over a metal layer). In one or more embodiments, the thickness of the control gate layer 250 may be about 300 Angstroms to about 3000 Angstroms, however, other thicknesses are also possible. The control gate layer 250 may be deposited in many different ways. Examples, include chemical vapor deposition, physical vapor deposition and atomic layer deposition.

In one or more embodiments, the control gate layer 250 may serve as a control gate layer for the control gate of a floating gate memory device or as a control gate of a charge trapping device. Hence, in one or more embodiments, the control gate layer 250 may be formed of a material which can serve as a control gate of a floating gate memory device or as the control gate of a charge trapping device.

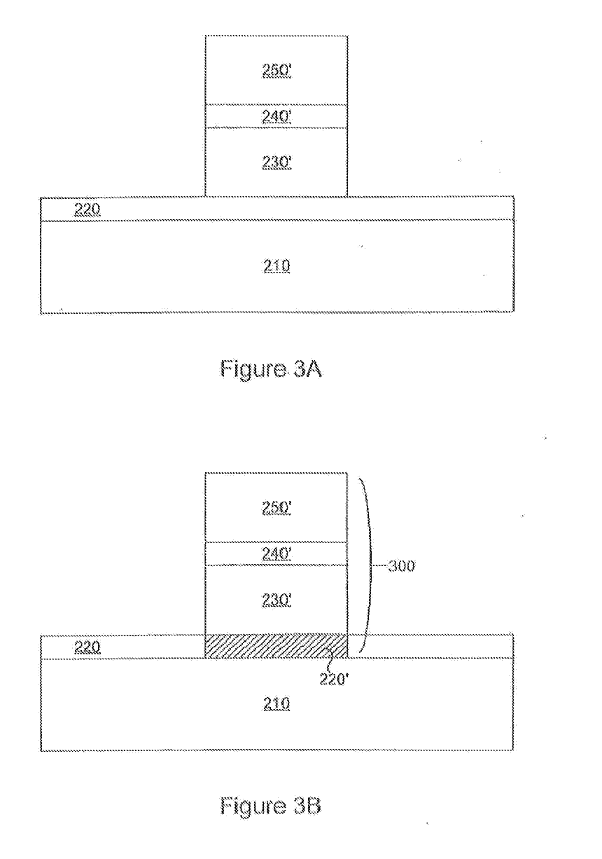

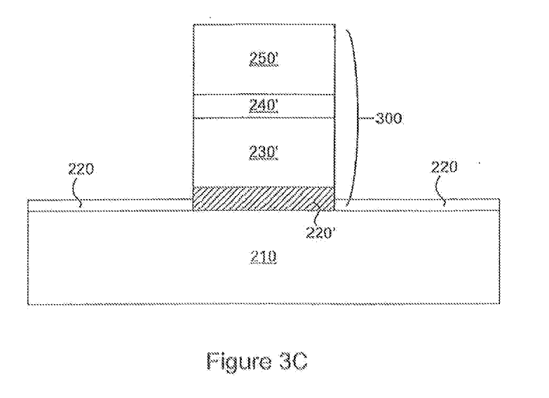

Referring to FIG. 2, in a subsequent processing step, the layers from FIG. 1 are masked and etched to form a gate stack 300. After pattering, a remaining portion of the first dielectric layer 220 forms a first dielectric layer 220′ of the gate stack 300. The first dielectric layer 220′ may also be referred to as the first gate dielectric 220′ of the gate stack 300. It is noted that, in one or more embodiments, the first gate dielectric layer 220 shown in FIG. 1 may not be etched during the formation of the gate stack 300 or the dielectric layer 220 may be only partially etched during the formation of the gate stack 300. For example, it is possible that the dielectric layer 220 serve as an etch stop layer during the formation of the gate stack. This embodiment is illustrated in FIGS. 3A and 3B. FIG. 3A shows a structure where only the layers 250, 240 and 230 from FIG. 1 have been etched. Referring to FIG. 3B, a remaining portion 220′ of the dielectric layer 220 (for example, a remaining portion 220′ which underlies the control gate 250′) may still be considered to be a dielectric layer 220′ which is part of the gate stack 300.

In one or more embodiments, it is also possible that the layer 220 from FIG. 1 be only partially etched. This is shown in FIG. 3C. Referring to FIG. 3C, it is seen that a remaining portion 220′ of the dielectric layer 220 may still be considered to be a dielectric layer 220′ which is part of the gate stack 300. Referring again to FIG. 2, after patterning, a remaining portion of the charge storage layer 230 forms a charge storage layer 230′ of the gate stack 300. After patterning, a remaining portion of the second dielectric layer 240 forms a second dielectric layer 240′ of the gate stack 300. The second dielectric layer 240′ may also be referred to as a second gate dielectric 240′ of the gate stack 300.

After patterning, a remaining portion of the control gate layer 250 forms control gate layer 250′ of the gate stack 300. The control gate layer 250′ may also be referred to as control gate 250′ of the gate stack 300.

In one or more embodiments, the control gate 250′ may serve as a control gate for a memory device such as a charge storage memory device. The charge storage memory device may be for example, a floating gate memory device or a charge trapping memory device.

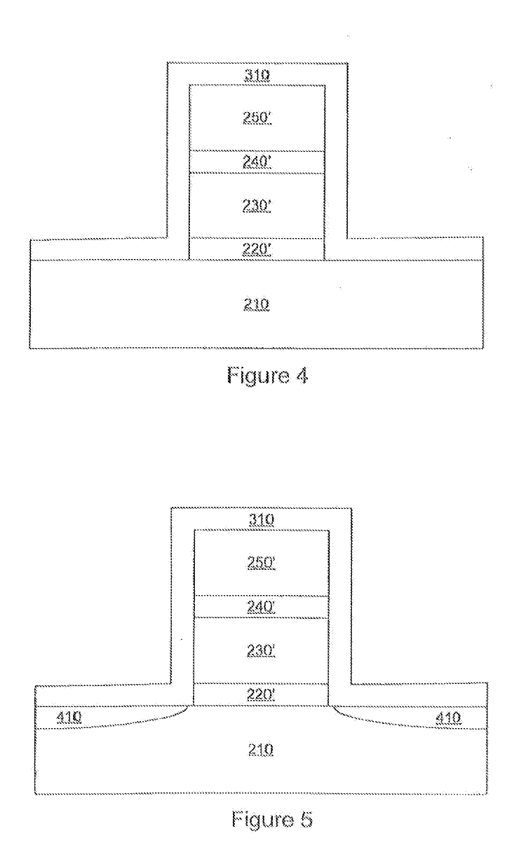

Referring to FIG. 4, in a subsequent process step a cover layer 310 may be formed over the top surface and sidewall surfaces of the gate stack 300 shown in FIG. 2. The cover layer 310 may also be formed over the top surface of the substrate 210. The cover layer 310 may be formed over the sidewall surfaces of the first gate dielectric layer 220′. The cover layer 310 may be formed over the sidewall surfaces of the second gate dielectric layer 240′. In one or more embodiments, the cover layer may be formed over the exposed portions of any high-k dielectric layer of the gate stack. A high-k dielectric layer is also referred to as a high-k layer. (It is noted that, in another embodiment, the process may be continued from the structure shown in FIG. 3B or from the structure shown in FIG. 3C).

In one embodiment, the cover layer 310 may comprise a dielectric material. In an embodiment the dielectric material may be an oxide material. An example, the oxide material may be silicon dioxide or SiO₂. In another embodiment, the cover layer 310 may comprise a nitride material. The nitride may be silicon nitride. In another embodiment, the cover layer 310 may comprise an oxynitride material. The oxynitride may, for example, be silicon oxynitride. In one embodiment, the cover layer 310 may be formed by a growth process. In another embodiment, the cover layer 310 may be formed by a deposition process. As an example, the cover layer 310 may be formed by the deposition of an oxide material such as the deposition of SiO₂. In one or more embodiments, the deposition of cover layer 310 may be a conformal deposition.

The deposition of the cover layer 310, which may comprise a silicon dioxide or some other oxide, may, for example, be carried out by High-Temperature Oxidation (HTO) or Low Temperature Oxidation techniques (LTO) or through some other way such as by Atomic Layer Deposition (ALD).

After the formation of the cover layer, the cover layer may be subjected to an annealing process which may increase the density of the cover layer material. This may improve the quality of the cover layer.

Referring to the embodiment shown in FIG. 4, it is seen that the cover layer 310 may be formed over the exposed sidewall surfaces of the first dielectric layer 220′ and/or the exposed sidewall surfaces of the charge storage layer 230′ and/or the exposed sidewall surfaces of the second dielectric layer 240′ and/or the exposed sidewall surfaces of the control gate layer 250′. This may be especially useful when either the first dielectric layer 220′ and/or the charge storage layer 230′ and/or second dielectric layer 240′ and/or the control gate layer 250′ comprise a high-k material.

The cover layer 310 (which may be formed of a deposited oxide such as a deposited silicon dioxide) may help to protect the high-k material during further processes. As well, the cover layer may help to protect processing tools from contamination. In order to integrate high-k material into a conventional process (such as a conventional CMOS process or a conventional embedded memory process) as an dielectric layer between a charge storage layer and a control gate layer, care may need to be taken to avoid contamination of the established process tool-park. In general, the constituents of a process using high-k materials may differ from those of a process without high-k process. Hence, the high-k materials may be regarded as contaminants. This may require regular contamination checks of the process tools involved in process steps where the high-k materials are exposed. This may be over a large number of process steps from high-k deposition to encapsulation after spacer processing. This slows process cycle times considerably. During these process steps, the high-k materials themselves may also be exposed to several processing steps (such as wet etching steps) which, owing to the different chemical properties of the high-k materials, may lead to unwanted etching of the high-k material. It is possible that the cover layer 310 may help prevent such tool contamination and/or such unwanted etching, as described above.

Referring to FIG. 5, after the formation of the cover layer 310, the structure may be subject to an ion implantation process to form source/drain extension regions 410. In one or more embodiments, the source/drain extension regions 410 may, for example, be lightly doped drain (LDD) regions. In one or more embodiments, the extension regions 410 may, for example, medium doped drain (MDD) regions.

In one or more embodiments, the extension regions 410 may be n-type. In one or more embodiments, the extension regions 410 may be p-type.

In one or more embodiments, during the formation of the extension regions 410, the control gate layer 250′ may also be doped with n-type or p-type dopants.

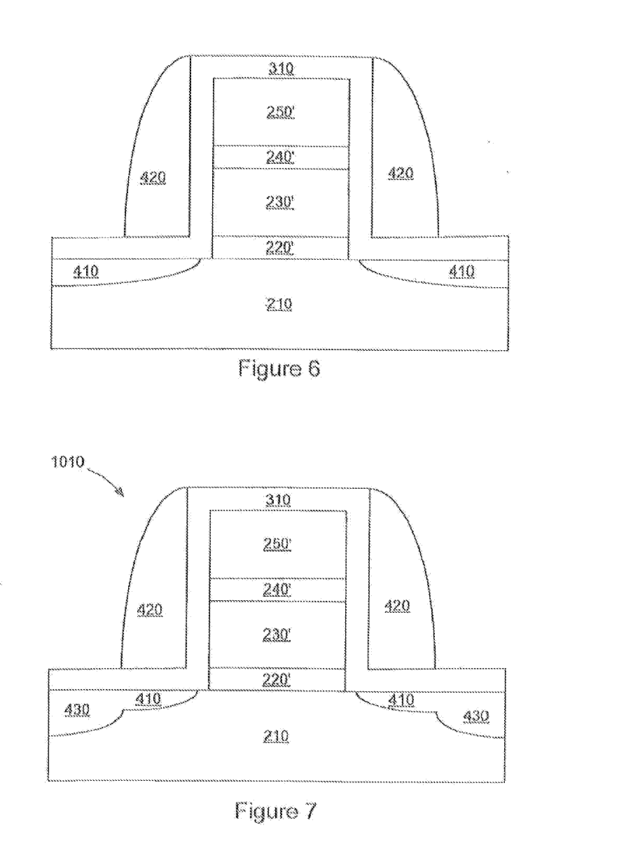

Referring to FIG. 6, after the formation of the extension regions 410 regions, sidewall spacers 420 may be formed over sidewalls of gate stack 300 and over the sidewalls of the cover layer 310. In one or more embodiments, the sidewall spacers 420 may, for example, comprise a dielectric material. Examples of dielectric materials include, but not limited to, oxides, nitrides, oxynitrides and mixtures thereof. The sidewall spacers 420 may, for example, be formed by the conformal deposition of a dielectric material followed by the anisotropic etch of the material.

In one or more embodiments, it is also possible that the sidewall spacers 420 comprise a polysilicon material. In an embodiment, the polysilicon material may be doped with an n-type and/or p-type material. In one or more embodiments, one of the spacers may be removed in later processing. In one or more embodiments, the remaining spacer may form a select gate for a memory device.

It is noted that after the formation of the extension regions 410 (as shown in FIG. 5) but before the formation of the sidewall spacers 420 (as shown in FIG. 6), a chemical-based cleaning step may optionally be performed. It is noted that the cover layer 310 may protect the sidewalls of the second dielectric layer 240′ from being etched by the chemical used during such a cleaning step. This may be useful when the second dielectric layer 240′ comprises a high-k dielectric material which may be particularly sensitive to the chemical cleaning agent.

Referring to FIG. 7, after the formation of the sidewall spacers 420, another ion implantation step may be performed to form the source/drain regions 430. In one or more embodiments, the source/drain regions 430 may be formed as heavily doped drain (HDD) regions. The dopant type of the source/drain regions 430 may be the same as the dopant type of the extension regions 410. The dopant concentration of the source/drain regions 430 may be greater than the dopant concentration of the extension regions 430. The depth of the source/drain regions 430 may be greater than the depth of the extension regions 410.

In one or more embodiments, during the formation of the source/drain regions 430, the control gate layer 250′ may also be doped with n-type or p-type dopants.

In one or more embodiments, the device 1010 shown in FIG. 7 may be useful as a memory device such as a charge storage memory device. In one or more embodiments, the charge storage memory device may be a floating gate memory device. In this case, the charge storage layer 230′ may be a floating gate layer or floating gate. The floating gate layer may be formed of a polysilicon material such as a doped polysilicon (n-doped or p-doped). The control gate layer 250′ may also be formed of a doped polysilicon. The first dielectric layer 220′ may be formed of an oxide, such as silicon dioxide (which may be formed by a growth process). The second dielectric layer 240′ may be formed of a high-k material. The cover layer 310 may be formed of a deposited oxide such as a deposited silicon dioxide. Of course, other materials may be substituted for the materials described.

In one or more embodiments, the charge storage memory device 1010 may be charge trapping memory device. In this case, the charge storage layer 230 may be a charge trapping layer. The charge trapping layer may comprise a nitrides (such as silicon nitride), oxynitrides, nanocrystalline materials and high-k materials. The first dielectric layer 220′ may also be an oxide (such as a silicon dioxide) which may be formed by a growth process. The second dielectric layer may be a high-k material, and the control layer 250′ may be doped polysilicon material. The cover layer 310 may be formed of a deposited oxide (such as a deposited silicon dioxide). Of course, other materials may be substituted for the materials described.

In one or more embodiments, the charge storage memory device 1010 shown in FIG. 7 may be a stand-alone memory device. In one or more embodiments, the charge storage memory device shown in FIG. 7, may be used as an embedded memory device in combination with at least one logic device on the same chip or the same substrate. Hence, the same chip (or same substrate) may include a memory portion (with one or more memory devices) and a logic portion (with one or more logic devices). In one or more embodiments, the same chip (or same substrate) may include a memory device and a high voltage transistor device.

When formed as an embedded memory device in combination with at least one logic device, the cover layer 310 may serve a useful role. Referring again to FIG. 5, after the formation of the extension regions 410 but before the formation of the sidewall spacers 420 (shown in FIG. 6), it is possible that a nitride hardmask be formed over both the memory portion and logic portion of the common chip or substrate. It is possible that an oxide (such as a TEOS oxide) be then formed over the nitride hardmask (over both the logic portion and the memory portion). The oxide may then be removed over only the memory portion but left over the logic portion (so as to expose the nitride hardmask over the memory portion).

A chemical such as phosphoric acid may then be used to remove the exposed TEOS oxide from the memory portion. In the case in which the second dielectric layer 240′ may be formed of a high-k material, it is then possible that the phosphoric acid may etch the high-k material if it where not protected by the cover layer 310.

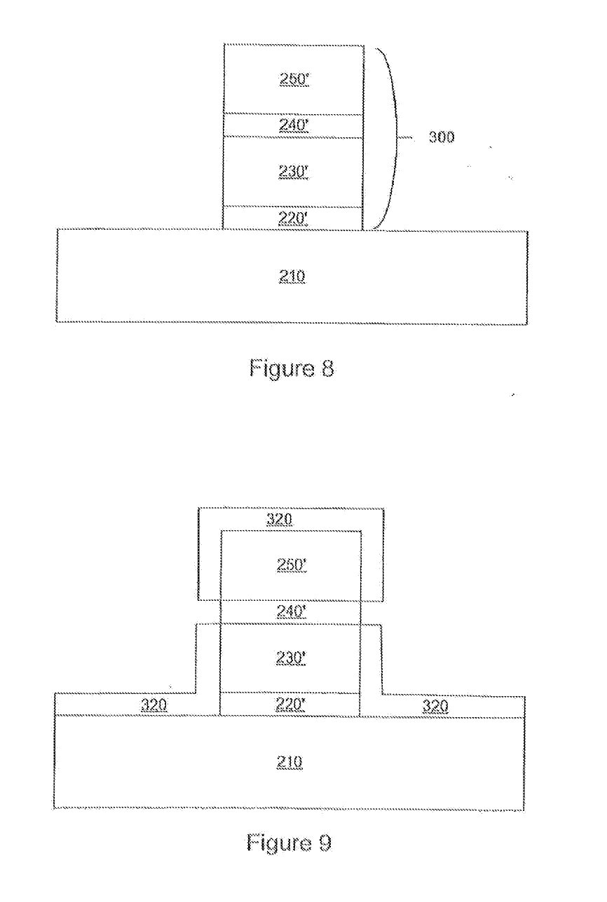

FIGS. 8 though 13 show an embodiment of a method for making a semiconductor device. In another embodiment, a pre-cover layer 320 may be formed over the gate stack 300 before the cover layer 310 is applied to the gate stack 300. FIG. 8 shows the same gate stack 300 from FIG. 2. In one or more embodiments, as shown in FIG. 9, a pre-cover layer 320 may be formed over at least a portion of the top and sidewall surfaces of the gate stack 300 as well as over the top surface of the substrate 210. It is noted that, in another embodiment, a pre-cover layer could instead be formed over the structure shown in FIG. 3B. Likewise, in another embodiment, a pre-cover layer could instead be formed over the structure shown in FIG. 3C.

In an embodiment, the pre-cover layer 320 may comprise a dielectric material. In an embodiment, the pre-cover layer 320 may include an oxide. An example of an oxide is silicon dioxide (SiO₂). Another example of an oxide is tantalum oxide. In an embodiment, the pre-cover layer 320 may include a nitride. An example of a nitride is silicon nitride. In an embodiment, the pre-cover layer may include an oxynitride. An example of an oxynitride is SiON. In an embodiment, the pre-cover layer may include SiOₓN_{y}. The pre-cover layer 320 may be formed by a growth process or by a deposition process.

In one or more embodiments, the deposition process may be a conformal deposition. In one embodiment, the pre-cover layer may comprise an oxide (such as a silicon dioxide) which is formed by a growth process (such as a thermal growth or oxidation process).

In the embodiment shown in FIG. 9, the pre-cover layer 320 is shown such that it does not form over the sidewall surfaces of the second dielectric layer 240′ (also referred to as a second gate dielectric 240′). For example, the second dielectric layer 240′ may comprise a high-k material. In one or more embodiments, the pre-cover layer 320 may comprise an oxide material (such as a silicon dioxide) that is formed by a growth process such as a thermal growth process. The oxide material may not be able to grow on the surface of the high-k material.

In other embodiments, it may be possible that a pre-cover layer may not form on one or more other layers of the gate stack 300. For example, it may be possible that one or more other layers of the gate stack 300 also comprise a high-k dielectric material.

In other embodiments, it may be possible that the pre-cover 320 can form (by, for example, growth or deposition) on the sidewall surfaces of the second dielectric layer 240′.

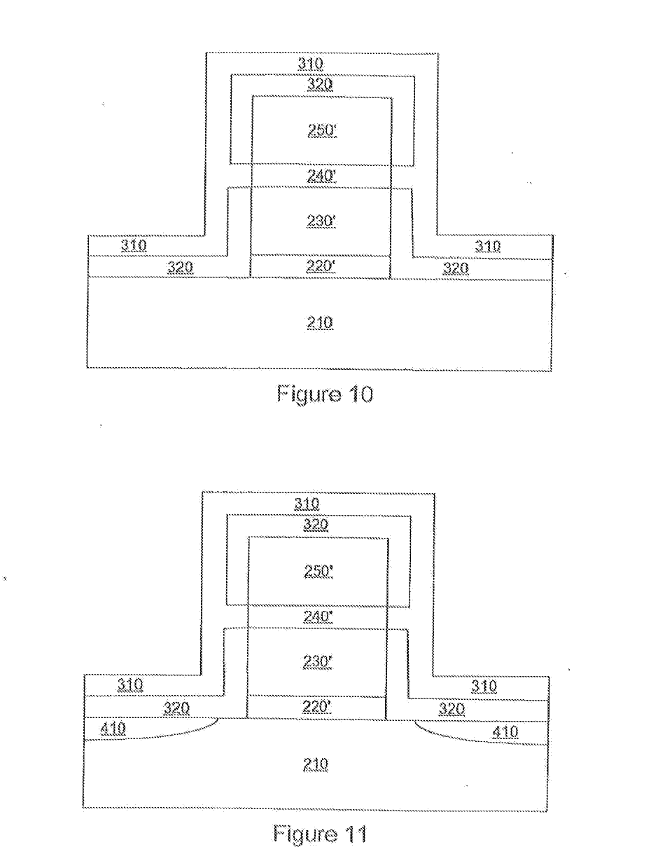

Referring to FIG. 10, after the formation of the pre-cover layer 320, a cover layer 310 may then be formed over the structure shown in FIG. 9. Hence, the cover layer 310 may be formed over the pre-cover layer 320 as well as over the sidewall surfaces of the second dielectric layer 240′. Referring to the embodiment shown in FIG. 10, the cover layer 310 is formed on the surface of the pre-cover layer 320 as well as on the sidewall surfaces of the second dielectric layer 240′.

In one or more embodiments, the cover layer 310 may comprise a dielectric material. In one or more embodiments, the cover layer 310 may be formed by a growth process. In one or more embodiments, the cover layer 310 may be formed by a deposition process. In one or more embodiments, the cover layer 310 may comprise an oxide material (such as a silicon dioxide). In one or more embodiments, the cover layer 310 may comprise an oxide material (such as a silicon dioxide) which is formed by a deposition process. The one or more embodiments, it is possible that the cover layer 310 may include other materials, such as other dielectric materials. In one or more embodiments, the cover layer 310 may comprise a nitride material. In one or more embodiments, the cover layer 310 may comprise an oxynitride material. The combination of the pre-cover layer 320 and the cover layer 310 may serve to protect the gate stack 300 during further processing.

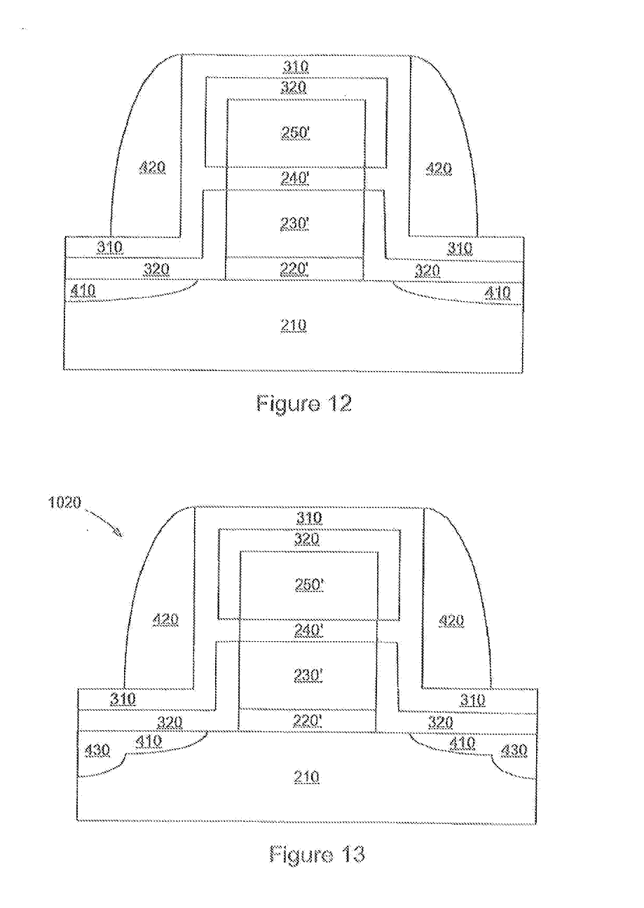

After the formation of the cover layer 310, the structure may be subject to an ion implantation process such as to form the source/drain extension regions 410 as shown in FIG. 11. In one or more embodiments, the extension regions 410 may, for example, be lightly doped drain (LDD) regions. In one or more embodiments, the extension regions 410 may, for example, be medium doped drain (MDD) regions 410. In one or more embodiments, the extension regions 410 may be n-type. In one or more embodiments, the extension regions 410 may be p-type. Referring to FIG. 12, after the formation of the extension regions 410 regions, sidewall spacers 420 may be formed over sidewalls of the cover layer 310. In one or more embodiments, the sidewall spacers 420 may comprise a dielectric material. Examples of dielectric materials include, but not limited to, oxides, nitrides, oxynitrides and mixtures thereof.

In one or more embodiments, the sidewall spacers 420 may comprise a polysilicon material such an n-doped or p-doped material. In a later processing step, it is possible that one of the spacers is removed. In one or more embodiments, it is possible that the remaining spacer may be used as a select gate for a memory device.

Referring to FIG. 13, after the formation of the sidewall spacers 410, another ion implantation step may be performed to form the source/drain regions 430. In one or more embodiments, the source/drain regions 430 may be formed has heavily doped drain (HDD) regions. The dopant type of the source/drain regions 430 may be the same as the dopant type of the extension regions 410. The dopant concentration of the source/drain regions 430 may be greater than the concentration of the extension regions 430. The depth of the source/drain regions 430 may be greater than the depth of the extension regions 410.

In one or more embodiments, the device 1020 shown in FIG. 13 may be useful as a memory device such as a charge storage memory device. In one or more embodiments, the charge storage memory device may be a floating gate memory device. In this case, the charge storage layer 230′ may be a floating gate layer or floating gate. The floating gate layer may be formed of a polysilicon material such as a doped polysilicon (n-doped or p-doped). The control gate layer 250′ may also be formed of a doped polysilicon. The first dielectric layer 220′ may be formed of an oxide, such as silicon dioxide (which may be formed by a growth process). The second dielectric layer 240′ may be formed of a high-k material. The cover layer 310 may be formed of a deposited oxide such as a deposited silicon dioxide. Of course, other materials may be substituted for the materials described.

In one or more embodiments, the charge storage memory device 1020 may be charge trapping memory device. In this case, the charge storage layer 230 may be a charge trapping layer. In one or more embodiments, the charge trapping layer may comprise a nitride (such as silicon nitride), oxynitrides, nanocrystalline materials and high-k materials. The first dielectric layer 220′ may be an oxide (such as a silicon dioxide) which may be formed by a growth process. The second dielectric layer may be a high-k material, and the control layer 250′ may be doped polysilicon material. The cover layer 310 may be formed of a deposited oxide (such as a deposited silicon dioxide). Of course, other materials may be substituted for the materials described.

In one or more embodiments, the device 1020 shown in FIG. 13 may be a charge storage memory device. In one or more embodiments, the charge storage memory device may be a stand alone memory device. In one or more embodiments, the charge storage memory device 1020 shown in FIG. 12, may be used as an embedded memory device in combination with at least one logic device on the same chip or the same substrate. Hence, the same chip (or same substrate) may include a memory portion and a logic portion.

When formed as an embedded memory device in combination with at least one logic device, the cover layer 310 as well as the pre-cover layer 320 may serve useful roles. Referring again to FIG. 10, after the formation of the extension regions 410 but before the formation of the sidewall spacers 420 (shown in FIG. 11), it is possible that a nitride hardmask be formed over both the memory portion and logic portion of the chip or substrate. It is possible that an oxide (such as a TEOS oxide) be then formed over the nitride hardmask. The oxide may then be removed over only the memory portion but left over the logic portion (so as to expose the nitride hardmask over the memory portion). A chemical such as phosphoric acid may then be used to remove the exposed TEOS oxide from the memory portion. If the second dielectric layer 240′ is formed of a high-k material, it is possible that the phosphoric acid may etch the high-k material if it where not protected by the cover layer 310. The pre-cover layer 320 may serve to provide additional protection for the layers 220′, 230′ and 250′.

In the embodiments shown in FIGS. 7 and 13, the second dielectric layer 240′ may comprise a high-k material (and this may hinder or prevent the growth of an oxide pre-cover layer 320 on the sidewall surfaces of the second dielectric layer 240′). In another embodiment, it is possible that the first dielectric layer 220′ may also comprise a high-k material. This high-k material may also hinder or prevent the growth of an oxide material on the sidewall surfaces of the first dielectric layer 220′. In yet another embodiment, it is possible that the first dielectric layer 220′ may comprise a high-k material but the second dielectric layer 240′ does not comprise a high-k material.

In yet another embodiment, it is possible that neither the first dielectric layer 220′ nor the second dielectric layer 240′ comprises a high-k material. Referring to FIGS. 9 through 13, in this case, the pre-cover layer 320 may form on and cover the sidewall surfaces of the first dielectric layer 220′ as well as the sidewall surfaces of the second dielectric layer 240′.

Although the invention has been described in terms of certain embodiments, it will be obvious to those skilled in the art that many alterations and modifications may be made without departing from the invention. Accordingly, it is intended that all such alterations and modifications be included within the spirit and scope of the invention.

What is claimed is:

1. A method of making a memory device, said memory device including a charge storage layer, said method comprising:
providing a substrate;
forming a gate stack over said substrate, said gate stack comprising said charge storage layer and a high-k dielectric layer; and
forming a cover layer over at least exposed surfaces of said high-k dielectric layer.

2. The method of claim 1, wherein said cover layer is formed by a deposition process.

3. The method of claim 1, wherein said cover layer comprises a dielectric material.

4. The method of claim 3, wherein said dielectric material is an oxide.

5. The method of claim 4, wherein said oxide is silicon dioxide.

6. The method of claim 1, wherein said high-k dielectric layer is between said charge storage layer and a control gate layer.

7. The method of claim 1, further comprising, after forming said cover layer forming source/drain extension regions in said substrate.

8. The method of claim 1, further comprising, after forming said cover layer, forming sidewall spacers over sidewall surfaces of said cover layer.

9. The method of claim 1, further comprising, after forming said cover layer, annealing said cover layer.

10. The method of claim 1, wherein said charge storage layer is a floating gate layer or a charge trapping layer.

11. The method of claim 1, further comprising the step of, after forming said gate stack and before depositing said cover layer, exposing said gate stack to a thermal oxidation process to grow an oxide layer over at least a portion of said gate stack.

12. A method of making a memory device, comprising:
providing a substrate;
forming a gate stack over said substrate, said gate stack including:
a first dielectric layer,
a charge storage layer formed over said first dielectric layer,
a second dielectric layer formed over said charge storage layer, and
a control gate layer formed over said second dielectric layer,
at least one of said first dielectric layer or said second dielectric layer comprising a high-k dielectric material; and
forming a cover layer over the sidewall surfaces of said gate stack so an to cover at least said high-k dielectric material.

13. The method of claim 12, wherein said cover layer is formed by a deposition process.

14. The method of claim 12, wherein said cover layer comprises a dielectric material.

15. The method of claim 13, wherein said dielectric material is an oxide.

16. The method of claim 13, wherein said oxide is silicon dioxide.

17. The method of claim 12, further comprising, before forming said cover layer, forming a pre-cover layer over at least a portion of said gate stack.

18. The method of claim 17, wherein said pre-cover layer is formed by a growth process.

19. The method of claim 17, wherein said pre-cover layer comprises an oxide.

20. The method of claim 12, further comprising:
after depositing said cover layer, exposing said cover layer to an annealing process.

21. The method of claim 12, further comprising:
after forming said cover layer, forming source/drain extensions in said substrate.

22. The method of claim 12, wherein said first dielectric layer comprises said high-k material.

23. The method of claim 12, wherein said second dielectric layer comprises said high-k material.

24. The method of claim 12, wherein first dielectric layer comprises a first high-k material and said second dielectric layer comprises a second high-k material.

25. The method of claim 24, wherein said first high-k material is the same as the second high-k material.

26. The method of claim 24, wherein said first high-k material is different from the second high-k material.
